(19) United States
(12) Patent Application Publication
(10) Pub. No.: US 2009/0101193 A1
(43) Pub. Date: Apr. 23, 2009

(54) SOLAR CELL ASSEMBLY

(75) Inventor: BOR-YUAN HSIAO, Tu-Cheng (TW)

Correspondence Address: PCE INDUSTRY, INC.;ATT. Steven Reiss, 458 E. LAMBERT ROAD, FULLERTON, CA, 92835, US

(73) Assignee: HON HAI PRECISION INDUSTRY CO., LTD., Tu-Cheng (TW)

(21) Appl. No.: 12/178,816

(22) Filed: Jul. 24, 2008

(30) Foreign Application Priority Data
Oct. 22, 2007 (CN) 200710202204.3

(51) Int. Cl. H01L 31/052

(52) U.S. Cl. 136/246

(57) ABSTRACT

A solar cell includes a plurality of solar panels arranged in parallel, and a light-reflective member adjacent to the plurality of solar panels. Each solar panel is spaced a predetermined distance from another, and the light-reflective member is configured for reflecting sunlight to the solar panels.

### BACKGROUND

1. Technical Field

The present invention generally relates to a solar cell assembly.

2. Description of Related Art

Currently, various solar cells have been designed to receive and convert sunlight into electrical energy. Such solar cells have been applied on roofs of buildings and cars, or applied on various portable electronic devices.

A typical solar cell mainly employs a solar panel made of semiconductor layers to convert sunlight into electrical energy. The solar panel includes a substrate, and a semiconductor layer arranged thereon. The semiconductor layer has a P-type semiconductor layer and an N-type semiconductor layer stacked on top of one another. When sunlight projects on a surface of the solar panel, a part of the sunlight is unavoidably reflected by the surface, and the other is absorbed. Photons in the absorbed sunlight collide with electrons in the semiconductor layer, thus, electron-hole pairs are generated in the semiconductor layer, and an electric field is formed between the P-type semiconductor layer and the N-type semiconductor layer. The electric field can power a load connected to the P-type semiconductor layer and the N-type semiconductor layer.

The photon-electron conversion efficiency of the solar cell is greatly limited by the surface area of the solar panel exposed to the sunlight. However, surface area of buildings, cars or the portable electronic devices are often not large enough to place the solar panel having a large surface area. Therefore, the typical solar cell has a low photo-electron conversion efficiency.

What is needed, therefore, is a solar cell assembly with a high photo-electron conversion efficiency.

### SUMMARY

A solar cell assembly, in accordance with a present embodiment, is provided. The solar cell assembly includes a plurality of solar panels and a light reflective member. The solar panels are arranged in substantially parallel with a predetermined distance from each other. The solar panels include an upper solar panel and a lower solar panel beneath the upper solar panel. The light-reflective member is located at two opposite sides of the solar panels, and is oriented in a manner such that sunlight incident on the light-reflective member is reflected and directed to the lower solar panel.

Other advantages and novel features will become more apparent from the following detailed description of embodiments, when taken in conjunction with the accompanying drawings.

### BRIEF DESCRIPTION OF THE DRAWINGS

Many aspects of the present solar cell assembly can be better understood with reference to the following drawings. The components in the drawings are not necessarily drawn to scale, the emphasis instead being placed upon clearly illustrating the principles of the present solar cell assembly. Moreover, in the drawings, like reference numerals designate corresponding parts throughout the several views.

FIG. 1 is an exploded perspective view of a solar cell assembly, in accordance with a first embodiment.

FIG. 2 is a schematic, cross-sectional view of the solar cell assembly shown in FIG. 1.

FIG. 3 is a schematic, cross-sectional view of a solar cell assembly, in accordance with a second embodiment.

The exemplifications set out herein illustrate various preferred embodiments, in various forms, and such exemplifications are not to be construed as limiting the scope of the present solar cell assembly in any manner.

### DETAILED DESCRIPTION

Reference will now be made to the drawings to describe, in detail, at least one preferred embodiment of the present solar cell assembly.

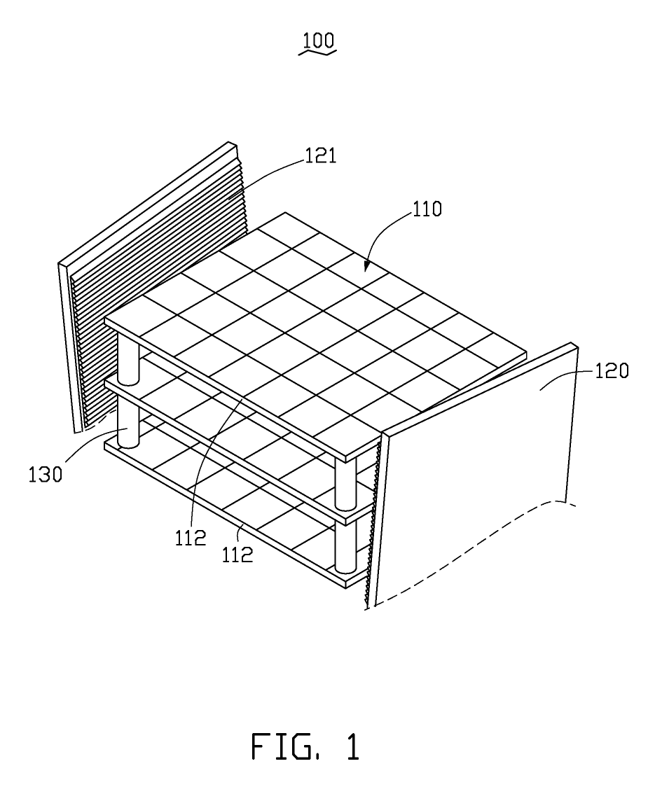

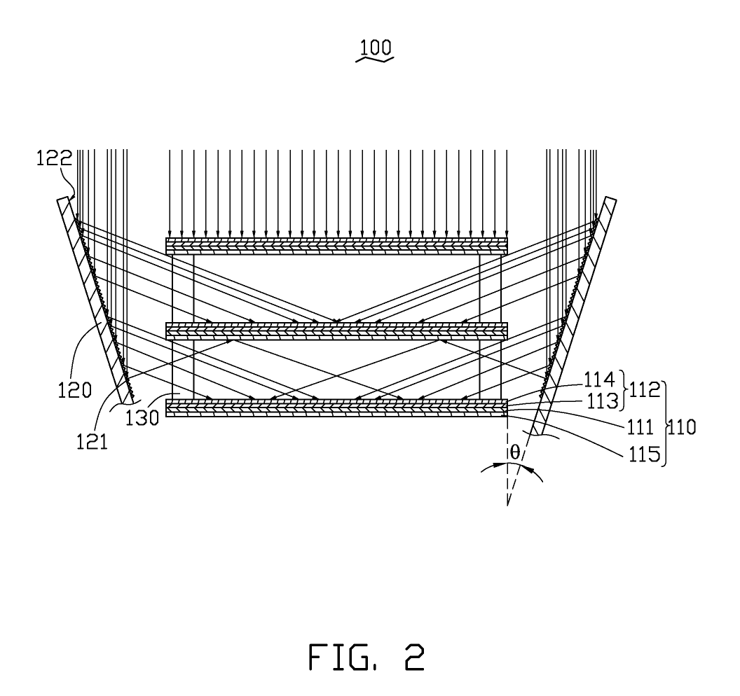

Referring to FIGS. 1 and 2, a solar cell assembly 100, in accordance with a first exemplary embodiment of the present invention, is provided. The solar cell assembly 100 includes a plurality of solar panels 110 and a light-reflective member 120 adjacent to the solar panels 110. The light-reflective member 120 has two light reflecting plates located at two opposite sides of the solar panels 110. The solar panels 110 are arranged in substantially parallel with a predetermined distance from each other. The solar panels 110 comprise an upper solar panel 118 and a lower solar panel 119 beneath the upper solar panel 118. Each light reflecting plates of the light-reflective member 120 is adjacent to the corresponding ends of the solar panels 110, and spans from the upper solar panel 118 to the lower solar panel 119. The light-reflective member 120 is configured for reflecting sunlight incident thereon to the solar panels 110. In this exemplary embodiment, the light-reflective member 120 is two light-reflective plates, and the two light-reflective plates 120 are arranged at opposite sides of the solar panels 110 and face toward each other.

Each of the solar panels 110 may include a semiconductor layer 112 consisting of a P-type semiconductor layer 113 and an N-type semiconductor layer 114 stacked together. The semiconductor layer 112 is configured for converting the sunlight irradiating thereon into electric power. In this exemplary embodiment, each of the solar panels 110 further includes a substrate 111, and the semiconductor layer 112 is arranged on the substrate 111.

The substrate 111 can be rigid or flexible according to need. The substrate 111 is comprised of a material selected from glass, single-crystal silicon, polysilicon, or stainless steel. The P-type semiconductor layer 113 is comprised of silicon doped with boron, or P-type compound. Such P-type compound can be selected from aluminum gallium arsenide (AlGaAs), or aluminum gallium nitride (AlGaN). The N-type semiconductor layer 114 is comprised of silicon doped with phosphorus, or N-type compound. Such N-type compound can be selected from gallium nitride (GaN), or indium gallium phosphide (InGaP). The P-type semiconductor layer 113 and the N-type semiconductor layer 114 are stacked together such that a P-N junction is formed therebetween. The P-type semiconductor layer 113 and the N-type semiconductor layer 114 may be deposited on the substrate 111 on top of one another by plasma-enhanced chemical vapor deposition (PECVD) or metal-organic chemical vapor deposition (MOCVD).

In this exemplary embodiment, each of solar panels 110 may further include a reflective layer 115 arranged on an opposite surface of the substrate 111 to the semiconductor layer 112. The reflective layer 115 of the solar panel 110 can reflect sunlight reflected and directed by the light-reflective plates 120 to the reflective layer 115, and to the next following solar panel 110 for improving the sunlight use ratio.

Each of the light reflective plates of the light-reflective member 120 has a reflective surface 122 facing the solar panels 110, and a plurality of micro reflective structures 121 formed on the reflective surface 122. The reflective surface 122 is configured for reflecting the sunlight irradiating thereon to the solar panels 110, and the micro reflective structures 121 formed thereon may improve the reflective efficiency of the reflective surface 122. The micro reflective structures 121 may be holophotal prism. The solar cell assembly 100 may further include a plurality of posts 130 arranged between every two adjacent solar panels 110 for spacing the every two adjacent solar panels 110.

An angle θ is defined between each light reflective plate of the light-reflective member 120 and a direction perpendicular to the plurality of solar panels 110. The angle θ may be less than 45 degrees. Each light reflective plate of the light-reflective member 120 also may be perpendicular to the plurality of solar panel 110, that is, the angle θ is 0 degree.

The present solar cell assembly 100 employs the two light-reflective plates of the light-reflective member 120 to reflect the sunlight to the solar panels 110, such that the solar panels 110 arranged in substantially parallel to each other can all be used to convert the sunlight to the electric power. Therefore, the solar panels 110 do not need a very large surface area exposed to the sunlight for achieving a high photo-electron conversion efficiency.

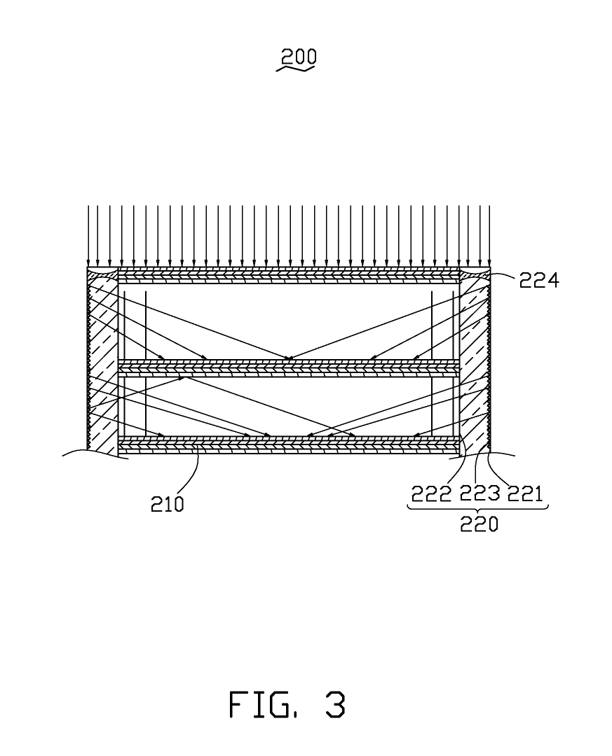

Referring to FIG. 3, a solar cell assembly 200, in accordance with a second exemplary embodiment of the present invention, is provided. The solar cell assembly 200 is similar to that of the first embodiment, except that the light-reflective member 220 is ring-shaped and surrounds the plurality of solar panels 210 therein. The light-reflective member 220 includes a transparent body, which has a light-emitting surface 222 adjacent to the sides of the plurality of solar panels 210 and a reflective surface 221 at an opposite side of the transparent body to the light-emitting surface 222. The reflective surface 221 is configured for reflecting the sunlight to the solar panels 210.

In this exemplary embodiment, the solar cell assembly 200 may further include a diverging lens 224 arranged on the light-reflective member 220 and adjacent to the upper solar panel. A plurality of micro reflective structures 223 are formed on the reflective surface 221 and facing the solar panels 210.

It is believed that the present embodiments and their advantages will be understood from the foregoing description and it will be apparent that various changes may be made thereto without departing from the spirit and scope of the invention or sacrificing all of its material advantages, the examples hereinbefore described merely being preferred or exemplary embodiments of the present invention.

What is claimed is:

1. A solar cell assembly, comprising:
a plurality of solar panels, the solar panels being arranged in substantially parallel to each other, and the solar panels being spaced a predetermined distance from each other, the solar panels including an upper solar panel and a lower solar panel beneath the upper solar panel; and
a light-reflective member disposed between the upper solar panel and the lower solar panel, the light-reflective member being oriented in a manner such that sunlight incident on the light-reflective member is reflected and directed to the lower solar panel.

2. The solar cell as claimed in claim 1, wherein each of the solar panels includes a semiconductor layer consisting of a P-type semiconductor layer and an N-type semiconductor layer.

3. The solar cell as claimed in claim 2, wherein each of the solar panels includes a substrate, and the semiconductor layer is arranged on the substrate.

4. The solar cell as claimed in claim 3, wherein each of the solar panels includes a reflective layer arranged on an opposite surface of the substrate to the semiconductor layer.

5. The solar cell as claimed in claim 1, wherein the light-reflective member includes two light-reflective plates, the two light-reflective plates are arranged at opposite sides of the solar panels and face toward each other.

6. The solar cell as claimed in claim 5, wherein each of the light-reflective plates has a reflective surface facing toward the solar panels, and a plurality of micro reflective structures are formed on the reflective surface and are configured for improving the reflective capability of the light-reflective plate.

7. The solar cell as claimed in claim 6, wherein the plurality of micro reflective structures are holophotal prisms.

8. The solar cell as claimed in claim 5, wherein an angle between each light-reflective plate and a direction perpendicular to the plurality of solar panels is less than 45 degrees.

9. The solar cell as claimed in claim 1, wherein the light-reflective member surrounds the plurality of solar panel therein.

10. The solar cell as claimed in claim 9, wherein the light-reflective member has a transparent body, and the transparent body having a light-emitting surface adjacent to the sides of the plurality of solar panels, and a reflective surface at an opposite side of the transparent body to the light-emitting surface, and the reflective surface is configured for reflecting the sunlight to the lower solar panel.

11. The solar cell as claimed in claim 10, further comprising a diverging lens arranged on the light-reflective member, adjacent to the upper solar panel.

12. The solar cell as claimed in claim 10, wherein a plurality of micro reflective structures is formed on the reflective surface and facing toward the solar panels.

13. The solar cell as claimed in claim 1, further comprising a plurality of spacers arranged between adjacent solar panels.
